(19) United States
(12) Patent Application Publication
(10) Pub. No.: US 2022/0386495 A1
(43) Pub. Date: Dec. 1, 2022

(54) ELECTRIC RANGE

(71) Applicant: LG ELECTRONICS INC., Seoul (KR)

(72) Inventors: Seunghak KIM, Seoul (KR); Junghyeon Cho, Seoul (KR)

(21) Appl. No.: 17/826,940

(22) Filed: May 27, 2022

(30) Foreign Application Priority Data
May 28, 2021 (KR) 10-2021-0069181

(51) Int. Cl. H05K 7/14; F24C 7/06; F24C 7/08; H05B 6/12

(52) U.S. Cl. CPC H05K 7/1427; F24C 7/067; F24C 7/083; H05B 6/1209

(57) ABSTRACT

An electric range is provided that may include a single base bracket configured to support and protect a control circuit board, thereby remarkably reducing a number of components in comparison to a conventional electric range.

### CROSS-REFERENCE TO RELATED APPLICATION(S)

This application claims priority to and the benefit of Korean Patent Application No. 10-2021-0069181, filed in Korea on May 28, 2021, the disclosure of which is incorporated herein by reference in its entirety.

### BACKGROUND

### 1. Field

An electric range is disclosed herein.

### 2. Background

Various types of cooking utensils or electric appliances are used to heat food or other items (hereinafter, collectively “food”) at home or in a restaurant. Such cooking electric appliances may include gas range using gas and electric ranges using electricity.

An electric range may be largely classified into a resistance heating type and an induction heating type. An electrical resistance type may generate heat by applying a current to a non-metallic heating element, such as a metal resistance wire and silicon carbide, and may heat an object, for example, a cooking vessel or container, such as a pot or a frying pan, by radiating or conducting the generated heat. An induction heating type may apply high-frequency power to a coil and generate a magnetic field around the coil, and may heat a heating target made of a metal material using an eddy current generated in the magnetic field. In other words, when a current is applied to a working coil or a heating coil, a heating target may be induction-heated to generate heat and the heating object may be heated by the generated heat.

A conventional induction heating type electric range having the above configuration includes a heating portion or heater on which a working coil is wound, a control circuit board configured to supply high-frequency power to the working coil, and a case accommodating the heater and the control circuit board. The case may be provided with means for fixedly supporting the control circuit board and means for connecting and grounding the control circuit board to the case.

Korean Patent Laid-Open Publication No. 2014-0124106, which is hereby incorporated by reference, (Patented Document 1) discloses a configuration of an electric range for supporting a control circuit board by using a support bolt which includes one end fixed to a bottom surface of a case and the other end fixed to the control circuit board. However, a plurality the support bolt disclosed in Patented Document 1 has to be provided so as to support the control circuit board at a plurality of positions. Accordingly, when a size of the control circuit board increases, a number of required support bolts must be increased to a significant level, thereby causing a problem in that the number is rapidly increased.

In addition, when using the support bolt, a process of fixing the support bolt to a bottom surface of the case and a control circuit board to the other end of the support bolt so as to fix one end of the support bolt must be additionally provided. Accordingly, there might be a problem in that manufacturing costs and a manufacturing time are rapidly increased.

In addition, the process of fixing one end of the support bolt to the case may proceed from a lower outside of the case. Accordingly, the support bolt must be assembled in a state in which the case is turned over or facilitate for assembling the support bolt must be required from a lower outer side of the case, thereby complicating a manufacturing process or requiring additional manufacturing facilities.

### BRIEF DESCRIPTION OF THE DRAWINGS

Embodiments will be described in detail with reference to the following drawings in which like reference numerals refer to like elements, and wherein:

FIG. 1 is an exploded perspective view of an electric range according to an embodiment;

FIG. 2 is an exploded perspective view showing components of the electric range shown in FIG. 1, except a cover plate;

FIG. 3 is an exploded perspective view of a heater and an upper bracket shown in FIG. 2;

FIG. 4 is a perspective view showing an assembled state of a base bracket, a control circuit board module, and a ventilation module disposed in a case shown in FIG. 2;

FIG. 5 is a perspective view showing a coupled state of the control circuit board module and the ventilation module with respect to the base bracket shown in FIG. 4;

FIG. 6 is an exploded perspective view of an air guide removed from FIG. 4;

FIG. 7 is a plane view illustrating an assembled state in which a base bracket, a control circuit board module, and a ventilation module are assembled inside of the case shown in FIG. 2;

FIG. 8 is a partially enlarged view of FIG. 7;

FIG. 9 is a partially enlarged view showing a state in which a control circuit board module is omitted in FIG. 8; and

FIGS. 10 and 11 are cross-sectional views, taken along line X-X of FIG. 8.

### DETAILED DESCRIPTION

Aspects, features, and advantages are specifically described hereinafter with reference to the accompanying drawings such that one having ordinary skill in the art to which embodiments pertain can easily implement the technical spirit. Hereinafter, descriptions of known technologies in relation to embodiments are omitted if they are deemed to make the gist unnecessarily vague. Hereinafter, embodiments are described with reference to the accompanying drawings. In the drawings, identical reference numerals can denote identical or similar components.

The terms “first” and “second”, for example, are used herein only to distinguish one component from another component. Thus, the components should not be limited by the terms. Certainly, a first component can be a second component unless stated to the contrary.

Throughout, each element may be singular or plural, unless stated to the contrary.

Hereinafter, expressions of ‘a component is provided or disposed in an upper or lower portion’ may mean that the component is provided or disposed in contact with an upper surface or a lower surface. The present disclosure is not intended to limit that other elements are provided between the components and on the component or beneath the component.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context. Terms such as “include” or “has” are used herein and should be understood that they are intended to indicate an existence of several components, functions or steps, disclosed in the specification, and it is also understood that greater or fewer components, functions, or steps may likewise be utilized.

Terms such as “include” or “has” are used herein and should be understood that they are intended to indicate an existence of several components, functions or steps, disclosed in the specification, and it is also understood that greater or fewer components, functions, or steps may likewise be utilized.

Throughout, the terms “A and/or B” as used herein can denote A, B or A and B, and the terms “C to D” can denote C or greater and D or less, unless stated to the contrary.

Hereinafter, embodiments will be described, referring to the accompanying drawings showing a configuration of an electric range 1 according to an embodiment.

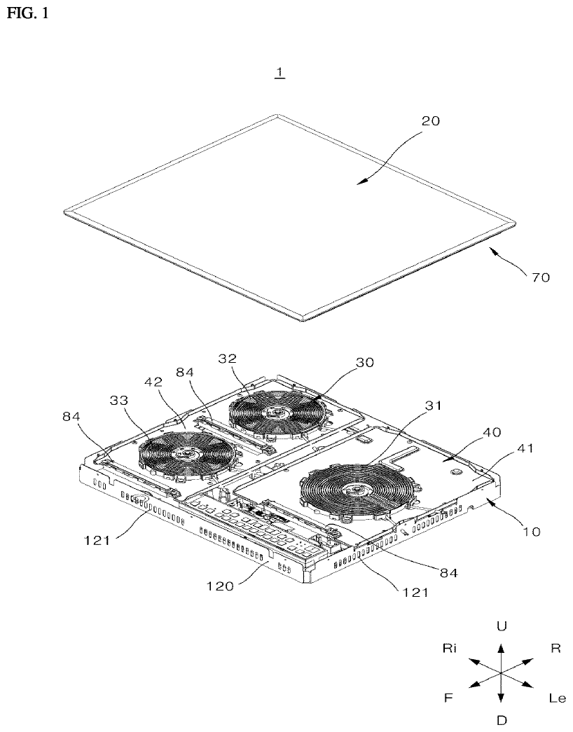

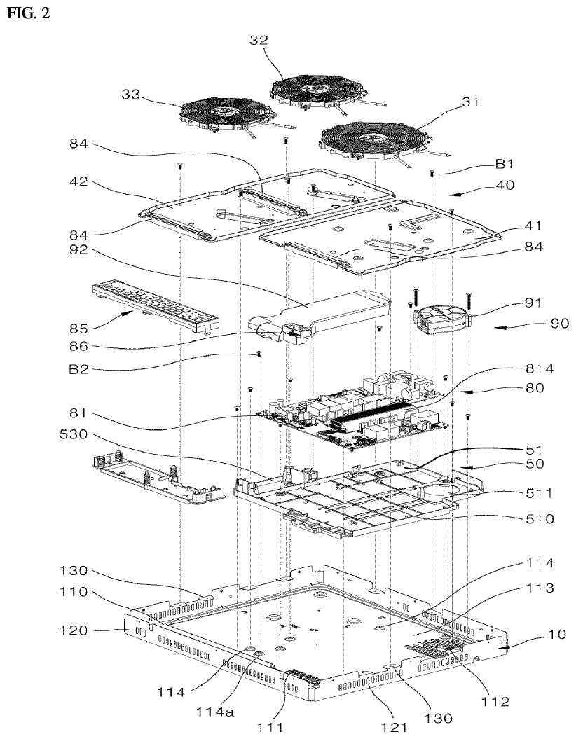

FIG. 1 is an exploded perspective view of an electric range according to an embodiment, in a state in which a cover plate is removed. FIG. 2 is an exploded perspective view showing components of the electric range shown in FIG. 1, except the cover plate. Referring to FIGS. 1 and 2, electric range 1 according to an embodiment will be described.

The electric range 1 according to this embodiment may be configured to heat a heating target based on an induction heating method. The heating target may be a tableware containing a metal material, for example, stainless steel and iron.

In the induction heating method, high-frequency power may be applied to a working coil 312, 322, and 332 to generate a magnetic field around the working coil 312, 322, and 332, and an eddy current generated by the magnetic field may be used in heating a heating target made of a metal material. More specifically, high-frequency power may be applied to a heating portion or heater 30 having a structure in which the working coil 312, 322, and 332 is disposed adjacent to a ferrite core, so that a magnetic field may be generated around the working coil 312, 322, and 332. When a heating target is placed in an area in the generated magnetic field, an eddy current may be induced in the heating object by the magnetic field and Joule's heat may be generated by the eddy current to heat the heating target. As the heating target is heated, food contained in the heating target may be heated.

The electric range may include a cover plate 20, the heater 30, an upper bracket 40, and a base bracket 50. The case 10 may be configured to define an exterior of the electric range and protect components of the electric range. For example, the case 10 may be made of a lightweight metal material, such as aluminum, for example; however, embodiments are not limited thereto.

The case 10 may be insulated to suppress heat generated by the working coil 312, 322, and 332 from being radiated to the outside. The case 10 may accommodate components of the electric range 1, such as the heater 30, the upper bracket 40, and a control circuit board module 80. A top of the case 10 may be open, and the open top may be closed by the cover plate 20.

The case 10 may be formed in a box shape by processing a plate-shaped material, for example. The case 10 may include a first casing 110, and a second casing 120.

The first casing 110 may define a bottom surface of the case 10. The first casing 110 may accommodate and support internal components installed in the electric range 1 in a downward direction. A plurality of extending portions formed by press working may be provided as a means for facilitating the accommodation and supporting of the internal components.

A downward extending portion 113 among the plurality of extending portions may be formed by press work to protrude the first casing 110 in a downward direction (D-direction) as a whole. The first casing 110 may protrude in the downward direction so that a space in a vertical direction (U-direction) may be secured for the internal components. In addition, a rigidity of the first casing 110 may be increased.

An area of the downward extending portion 113 may be larger than an area of the base bracket 50 so that the base bracket 50 may be included in the downward extending portion 113 as a whole.

An upward extending portion 114 may protrude upward from the downward extending portion 113 (U-direction), and may be formed as a circular bead as shown in the drawing, for example. The upward extending portion 114 may be formed at a plurality of positions, and may support a lower surface of the base bracket 50, which will be described hereinafter, to fix the base bracket 50.

To secure the base bracket 50 using a fastener, such as a substrate fastening bolt B2, for example, a bolt hole 114a may be formed in the upward extending portion 114, and the substrate fastening bolt B2 may penetrate the bolt hole 114a and extend therethrough. The substrate fastening bolt B2 may extend, passing through the main circuit board 811 and the base bracket 50, so that the main circuit board 811 and the base bracket 50 may be fixed to the first casing 110. The substrate fastening bolt B2 configured to secure the base bracket 50 may have a securing direction from top to bottom (D-direction).

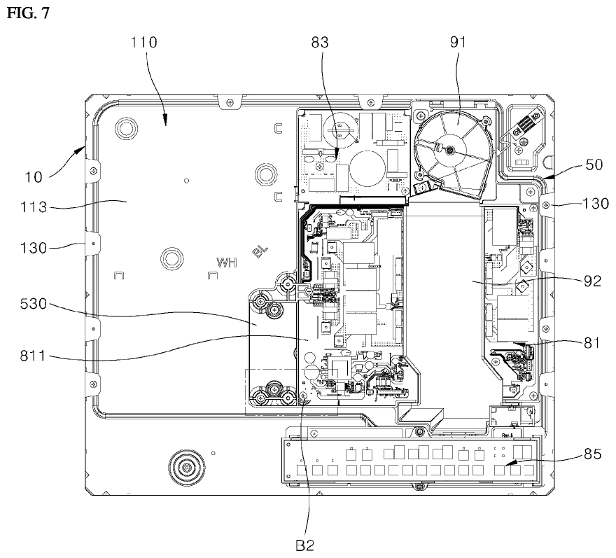

As the upward extending portion 114 protrudes from the downward extending portion 113, there may be a margin for preventing the substrate fastening bolt B2 from extending downward over the first case 110. A securing structure of the base bracket 50 and the main circuit board 811 using the substrate fastening bolt B2 will be described hereinafter, referring to FIG. 7.

The first casing 110 may include an air inlet hole 112 for through which air is drawn therein, and an air outlet hole 111 through which air is discharged therefrom, to facilitate cooling of the control circuit board module 80 provided therein and circuit elements mounted on the control circuit board module 80. As shown in FIG. 2, the air outlet hole 111 and the air inlet hole 112 may be provided in the form of a grill, thereby preventing inflow of foreign substances.

The second casing 120 may be bent from the first casing 110 and configured to define a lateral surface of the case 10. The second casing 120 may be bent from an edge of the first casing 110 in a vertical direction (U-D direction) to form a side wall of the electric range 1, so that the second casing 120 may surround the base bracket 50, which will be described hereinafter.

The second casing 120 may be formed on each side of the first casing 110 formed in a substantially quadrangular shape. The second casing 120 may reinforce a rigidity of the entire case 10. More specifically, the second casing 120 bent from the first casing 110 may be configured to prevent the plate-shaped first casing 110 from bending or being damaged by a weight of the internal components or an external force.

The second casing 120 may further include a plurality of ventilation hole 121 formed in a slit shape. The plurality of ventilation holes 121 may facilitate communication between an inside and an outside of the case 10 so that air may flow through the plurality of ventilation holes 121, thereby contributing to cooling of the internal components provided in the case 10.

A supporting flange 130 may be provided in an upper end of the second casing 120. The supporting flange 130 may be bent from an upper end of the second casing 120 toward the inside of the case 10, and may serve to support the upper bracket 140, which will be described hereinafter, from a lower surface. For example, the supporting flange 130 may be formed at a plurality of positions by bending upper ends of a left or first lateral surface, a right or second lateral surface and a rear surface of the second casing 110. A securing hole 131 for bolting fastening may be provided in each of the supporting flanges 130.

A bottom surface of the upper bracket 40 may be disposed on an upper surface of the supporting flange 130. The upper bracket 40 and the supporting flange 130 may be coupled to each other by a securing means, such as a bracket securing bolt B1, for example. A left or first lateral side end and a rear end of the first upper bracket 41 and a right or second lateral side end and a rear end of the second upper bracket 42 may be supported and coupled to each other by the supporting flange 130. The right side end of the first upper bracket 41 and the left side end of the second upper bracket 42 may be supported by a supporting bracket 530, which will be described hereinafter.

The cover plate 20 may be coupled to an upper end of the case 10 and a heating target may be placed on the upper surface of the cover plate 20. The cover plate 20 may be configured to close the open top of the case 10 to protect the internal components of the case 10.

The heating target may be placed on the upper surface of the cover plate 20 and a magnetic field generated from the heater 30 may pass through the cover plate 20 to reach the heating target. For example, the cover plate 20 may be made of a material having excellent heat resistance, such as ceramic or tempered glass, for example; however, embodiments are not limited thereto.

An input interface (not shown) configured to receive an operation input from the user may be provided on the upper surface of the cover plate 20. The input interface may be disposed on a predetermined area of the upper surface of the cover plate 20 and display a specific image.

The input interface may receive a touch input from the user, and the electric range 1 may be operated based on the received touch input. For example, the input interface may be a module configured to input a desired heating intensity or heating time by a user, and may be implemented as a physical button or a touch panel.

A touch circuit board module 85 configured to receive a user's touch manipulation input may be provided under the input interface, that is, under the cover plate 20. The touch circuit board module 85 may include a plurality of key switches 851 and a touch circuit board 851 on which the plurality of key switches 851 are mounted. The user may input a command to the touch circuit board module 85 via the plurality of key switches 851 to control operation of the electric range 1.

In the electric range 1 according to an embodiment, an upper surface of the touch circuit board module 85 may be in close contact with a lower surface of the cover plate 20. The touch circuit board module 85 may be disposed at a position corresponding to the input interface.

The touch circuit board module 85 and the input interface may be connected to each other by a capacitive touch input method. Accordingly, when the user inputs a control command to the input interface, the control command may be input to the touch circuit board module 85.

In addition, a display may be provided on or at a predetermined area of the upper surface of the cover plate 20 and configured to display an operation state of the electric range 1. A light display region may be formed on the upper surface of the cover plate 20. An light emitting diode (LED) substrate module 84 may be disposed under the cover plate 20, corresponding to the light display region. The light irradiated from the LED substrate module 84 may be transmitted to the user via the light display region. For example, the LED substrate module 84 may be fixedly disposed on the upper bracket 40, which will be described hereinafter. The upper bracket 40 may include a plurality of substrate supporting portions or supports 417 and 427 to support the LED substrate module 84.

The light display region and the LED substrate module 85 may be disposed in or at positions corresponding to each other. When a plurality of LED substrate modules 84 is provided, a same number of light display regions may be disposed on the upper surface of the cover plate 20.

The electric range 1 according to one embodiment may further include a cover bracket 70 configured to support the cover plate 20 and connect the cover plate 20 to the case 10. As shown in FIG. 1, the cover bracket 70 may be disposed on or at an outside of the upper bracket 40 and the case 10, and may be coupled to the case 10, to support the cover plate 20. For example, the cover bracket 70 may be coupled to the case 10 by a securing means, such as a case securing bolt (not shown), for example.

A plurality of the cover bracket 70 may be provided, and each of the plurality of cover brackets 70 may be disposed on or at a position corresponding to each side of the cover plate 20 formed in a quadrangle. For example, a total of fourth cover brackets 70 may be disposed on respective sides of the rectangular cover plate 20.

A plurality of the heaters 30 may be provided disposed under the cover plate 20, to heat a heating target. A total of three heaters 30 are shown in the accompanying drawings.

The plurality of heaters 30 may all employ the induction heating method, or some of the heaters 30 may employ the induction heating method and the others may be a highlight heating device using an electric resistance heating method, so that the electric range 1 may be configured as a so-called “hybrid range”.

Hereinafter, the electric range 1 including a plurality of heaters 30 all employing the induction heating method will be described.

The plurality of heaters 30 may be configured to have a same heating capacity or different heating capacities from each other. The accompanying drawings show an example of the plurality of heaters including first heater 31, second heater 32, and third heater 33; however, embodiments are not be limited thereto. An example of the first heater 31, the second heater 32, and the third heater 33 having different heating generation capacities will be described as a standard.

The first heater 31 may be secured to the first upper bracket 41. The second heater 32 and the third heater 33 may be secured to the second upper bracket 42.

The heaters 31, 32, and 33 may include core frames 311, 322, and 332, respectively. The working coils 312, 322, and 332 may be spirally wound around upper surfaces of the core frames 311, 321, and 331, respectively, and ferrite cores 313, 323, and 333 may be mounted on lower surfaces of the core frames 311, 321, and 331, respectively. Accordingly, when high-frequency power is applied to the working coils 312, 322, and 332, a magnetic field may be formed around the ferrite core 313, 323, and 333, and an eddy current may be formed in a heating target by the formed magnetic field.

Each of the working coils 312, 322, and 332 may include a pair of outgoing wires 312a, 322a, and 332a. An outgoing tip terminal may be provided at ends of each lead wire 312a, 322a, and 332a.

A temperature sensing portion or sensor 60 may be provided in a center of each heater 31, 32, and 33. More specifically, a first temperature sensing portion or sensor 61 may be provided in the first heater 31, and a second temperature sensing portion or sensor 62 may be provided in the second heater 32. A third temperature sensing portion or sensor 63 may be provided in the third heater 33.

The first temperature sensor 61 may include a first plate temperature sensor 611 configured to sense a temperature of the cover plate 20 directly above the first heater 31, a first thermal fuse 613 configured to detect whether the temperature of the cover plate 20 increases above a preset or predetermined threshold temperature, a first coil temperature sensor 612 configured to sense a temperature of the first working coil 312, and a first sensor holder 614 in which the first plate temperature sensor 611 and the third thermal fuse 613 are mounted. Similarly, the second temperature sensor 62 and the third temperature sensor 63 may have substantially a same configuration as the first temperature sensor 61, respectively. The second temperature sensor 62 may include a second plate temperature sensor 621, a second coil temperature sensor 622, a second thermal fuse 623, and a second sensor holder 624. The third temperature sensor 63 may include a third plate temperature sensor 631, a third coil temperature sensor 632, a third thermal fuse 633, and a third sensor holder 634.

The first to third plate sensors 611, 621, and 631 may directly contact a lower surface of the cover plate 20 so as to measure the temperature of the cover plate 20. Sensing surfaces may be disposed to maintain a contact state with the lower surface of the cover plate 20 at all times.

The first to third coil temperature sensors 612, 622, and 632 may be disposed on lower surfaces of the working coils 312, 322 and 332, and may directly contact the working coils 312, 322 and 332 so as to measure the temperature of the working coils 312, 322 and 332. Sensing surfaces may be disposed to maintain a contact state with the working coils 312, 322 and 332 at all times.

The first to third fuses 613, 623, and 633 may serve as a kind of a thermostat configured to disconnect an internal circuit when the temperature of the cover plate 20 increases above a preset or predetermined threshold temperature. When internal circuits of the first to third thermal fuses 613, 623, and 633 are cut off, the power supplied to the working coils 312, 322 and 332 may be immediately cut off to discontinue operation of the heaters 31, 32 and 33 in which overheating occurs.

The heaters 31, 32 and 33 may be disposed on and supported by the upper bracket 40. As in the example shown in the drawing, a plurality of the upper bracket 40 may be provided. The upper bracket 50 may include first upper bracket 41 that supports the first heater 31, and second upper bracket 42 that supports the second heater 32 and the third heater 33.

The upper bracket 40 may be made of a lightweight metal material, for example, aluminum; however, embodiments are not be limited thereto. The first upper bracket 41 may include a first upper plate 411 and a second upper plate 412. The first upper plate 411 may define a bottom surface of the first upper bracket 41 and the first heater 31 may be mounted on the first upper plate 411. The second upper bracket 42 may include a first upper plate 421 and a second upper plate 422. The first upper plate 421 may define a bottom surface of the second upper bracket 42, and the second heater 32 and the third heater 33 may be mounted on the first upper plate 421.

The first upper plate 411 of the first upper bracket 41 and the first upper plate 421 of the second upper bracket 42 may completely cover a main circuit board module 81 and a power circuit board module 83 provided under the first upper plates 411, 421 in the vertical direction (U-D direction). Due to this structure, the first upper plate 411 of the first upper bracket 411 and the first upper plate 421 of the second upper bracket 42 may serve to shield the electromagnetic field and electromagnetic waves generated from the heater 30 from reaching elements mounted on the main circuit board module 81 and the power circuit board module 83. More specifically, the first upper bracket 41 and the second upper bracket 42 may be configured to improve electromagnetic compatibility (EMC) and electromagnetic interference (EMI) performance of the circuit boards.

The second upper plate 412 of the first upper bracket 41 and the second upper plate 422 of the second upper bracket 422 may be bent from respective first upper plates 411 and 421 in the vertical direction (U-D direction) of the electric range 1. As shown in the drawing, the second upper plates 412 and 422 may be formed at sides of the first upper plates 411 and 421 formed in a substantially quadrangular shape.

A rigidity of the first upper bracket 41 and the second upper bracket 42 may be reinforced as a whole by the second upper plates 412 and 422. That is, the second upper plates 412 and 422 may prevent the plate-shaped first upper plates 411 and 421 from being bent or damaged by the weight of the internal components including the heater 30 or an external force.

Each of the first upper plates 411 and 421 may include the pair of outgoing wires 312a, 322a and 332a discussed above, and a plurality of insertion holes penetrated by lead wires (not shown) of the temperature sensor 60. For example, the plurality of insertion holes may include a first insertion hole 414 and 424 through which one of the pair of the outgoing wires 312a, 322a, and 332a passes, and a second insertion hole 415 and 425 through which the other one of the outgoing wires passes, and a third insertion hole 416 and 426 through which a lead wire of the temperature sensor 60 passes. The pair of lead wires 312a, 322a, and 332a and the lead wire of the temperature sensor 60 may pass through the insertion holes and extend in the downward direction (D-direction), thereby being electrically connected to the control circuit board module 80.

In addition, the first upper plate 411 and 421 may include a plurality of extending portions that protrudes in the upward direction (U-direction) or the downward direction (D-direction). The plurality of extending portions that protrudes in the downward direction (D-direction) may be referred to as an anti-pressing portions 411a, 421a. The anti-pressing portions 411a, 421a may serve to prevent the lead wires 312a, 322a that extend outward in a radial direction (r-direction_ from a center of each heaters 31, 32, and 33 among the pair of lead wires 312a, 322a, and 332a from being pressed in a mounting process of the heaters 31, 32, and 33. More specifically, the anti-pressing portions 411a, 421a may serve as passages for the outgoing wire 312a, 322a, and 332a that extend outward from the center of the heaters 31, 32, and 33.

The extending portion that protrudes in the upward direction (U-direction) may be referred to as a securing portion 413. The securing portion 413 may support the heaters 31, 32, and 33, and may prevent the securing means, such as bolts, from extending in the downward direction (D-direction) after passing through the first upper plate 411 and 421. In other words, the securing portion 413 may provide a margin for preventing the securing means, for example, bolts, from interfering with the control board circuit module 80 disposed in the downward direction (D-direction).

The LED substrate module 84 may be disposed on each of the first upper bracket 41 and the second upper bracket 42. Substrate support portions or supports 417 and 427 that support the LED substrate module 84 may be formed in the first upper plate 411 of the first upper bracket 41 and the first upper plate 421 of the second upper bracket 421, respectively. The substrate supporting portions 417 and 427 may be formed by partially cutting-away the first upper plate 411 of the first upper bracket 41 and the first upper plate 421 of the second upper bracket 42.

In the example shown in the drawing, one substrate supporting portion 417 may be provided in the first upper bracket 41 on which the first heater 31 is disposed. Two substrate supporting portions 427 may be formed in the first upper bracket 41 on which the second heater 32 and the third heater 33 are disposed.

A plurality of LEDs may be aligned on the LED substrate module 84. The plurality of LEDs may be luminescent when the heater 30 is turned on so that the user may be visually informed of whether the heater 30 is in operation or an operation state. The LED substrate module 84 may change a luminescent shape, and/or color, for example, of the plurality of LEDs to inform the user whether or not the electric range 1 is operating and the operation state.

The base bracket 50 may be disposed under the first upper bracket 41. The main circuit board module 81, and the power circuit board module 83 of the control circuit board module 80 may be mounted on the base bracket 50. The base bracket 50 may support the main circuit board module 81, the power circuit board module 83, and a ventilation module 90. The upward extending portions 114 formed in the first casing 110 may support a lower surface of the base bracket 50 at a plurality of positions.

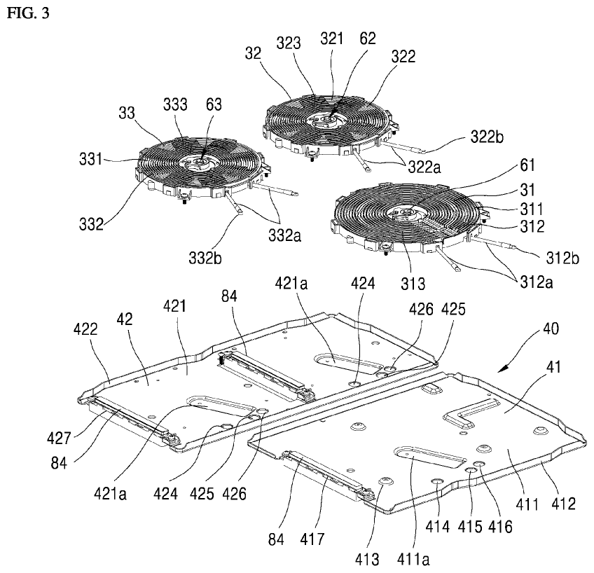

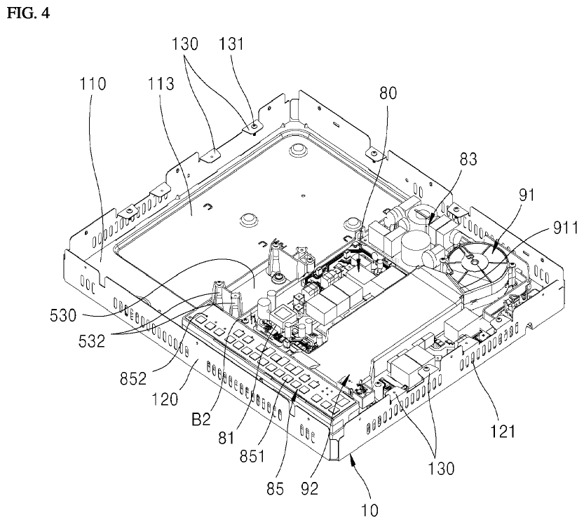

As shown in FIGS. 3 and 4, the base bracket 50 may include a board bracket 51 including a bottom plate 510 and a lateral plate 520. The bottom plate 510 may define a bottom surface of the base bracket 50. The main circuit board module 81, the power circuit board module 83, and the ventilation module 90 may be mounted on an upper surface of the bottom plate 510.

Substrates 811 and 831 provided in the main circuit board module 81 and the power circuit board module 83 may be secured to the bottom plate 510 via a plurality of substrate fastening bolts B2. Each substrate fastening bolt B2 may extend to the upward extending portion 114 of the first casing 110 to be screw-fastened. The substrates 811 and 831 of the main substrate module 81 and the power circuit module 83 and the bottom plate 510 may be secured at the same time to the upward extending portion 114 of the first casing 110 using the substrate fastening bolt B2.

Further, any one of the substrate fastening bolts B2 may be configured to act as a grounding means for grounding the main circuit board module 81 and the power circuit board module 83. For example, as shown in FG. 5, a copper-foil-shaped ground terminal may be formed around a bolt hole 816 of the main circuit board module 81 through which the substrate fastening bolt B2 extends, and a head B21 of the substrate fastening bolt B2 may be electrically connected to the ground terminal 817. A stem portion B22 of the substrate fastening bolt B2 may be physically and electrically connected to the upward extending portion 114 of the first casing 110. Through such a simple configuration, the main circuit board module 81 may be effectively grounded to the first casing 110 by the substrate fastening bolt B2. Although not shown, a same type of a ground terminal (not shown) may be provided in any one of the plurality of bolt holes 833 formed in the substrate 831.

The lateral plate 520 may extend in the upward direction (U-direction) of the electric range 1 from a lateral surface edge of the bottom plate 510. The lateral plate 520 may serve to reinforce the rigidity of the entire base bracket 50. That is, the lateral plate 520 may prevent the plate-shaped bottom plate 510 from being bent or damaged by the weight of the internal components, for example, the circuit board, or an external force. Further, the lateral plate 520 may also serve to protect the main circuit board module 81, the power circuit board module 83, and the ventilation module 90 from the external force applied to the bottom plate 510 in a lateral direction or frontward-rearward direction (F-R direction). For that, the lateral plate 520 may protrud to a position higher than a position in the vertical direction (U-D direction) of at least the main circuit board 811 and the power circuit board 831.

A supporting bracket 530 configured to support the first upper bracket 41 and the second upper bracket described above may be provided in or at a position corresponding to a center of the electric range 1. The supporting bracket 530 may extend parallel to a lateral surface of the board bracket 51 and a right surface with respect to the drawing. The supporting bracket 530 may be integrally formed with the board bracket 51. At this time, the supporting bracket 530 may be integrally formed with the board bracket 51, but may be configured to be easily decoupled from each other by an external force. For example, a connection portion between the supporting bracket 530 and the board bracket 51 may have a relatively weak strength.

The supporting bracket 531 may include a plurality of supporting bosses 531 that extends in the upward direction (U-D direction) from a bottom surface a first upper bracket toward the first upper bracket 41 and the second upper bracket 42 described above.

As mentioned above, left and rear ends of the first upper bracket 41 and right and rear ends of the second upper bracket 42 may be supported by and coupled to the supporting flanges 130. The right end of the first upper bracket 41 and the left end of the second upper bracket 42 may be supported and secured by the supporting bosses 531 of the supporting bracket 530. To couple the right end of the first upper bracket 41 and the left end of the second upper bracket 42 to each other, a coupling hole 532 may be formed in an upper end of each supporting boss 531.

In the example shown in the drawing, a total of five supporting bosses 531 may be provided in the supporting bracket 530. Not all of the five supporting bosses 531 may be used in coupling the right end of the first upper bracket 41 and the left end of the second upper bracket 42. For example, only three supporting bosses 531 out of the five supporting bosses 531 may be used in the coupling between the first upper bracket 41 and the second upper bracket 42.

The other supporting bosses 531 not used in the coupling according to the illustrated example may be used when the supporting bracket 530 supports the first upper bracket 41 and the second upper bracket 42 at a different position in another example. More specifically, when applied to another example of an electric range having a larger size than the electric range described above, the supporting bracket 530 may be decoupled from the board bracket 51 and moved to another position. When the supporting bracket 530 is applied to the larger-sized electric range, the other supporting bosses 531 not used in the coupling in this example may be used. The supporting bracket 530 is configured to be applicable to other examples, thereby facilitating component sharing and reducing manufacturing costs.

As described above, the main circuit board module 81 and the power circuit board module 83 of the control circuit board module 80 may be mounted on the base bracket 50. Although not limited thereto, the control circuit board module 80 may be understood as a higher concept including the above-noted LED substrate module 84, the touch circuit board module 85, and wireless communication substrate module 86 rather than the main circuit board module 81 and the power circuit board module 83.

As shown in FIGS. 3 and 4, the main circuit board module 81 may include a controller configured to control overall operation of the electric range 1, and may be electrically connected to the touch circuit board module 85 and the LED substrate module 84 described above. Accordingly, the main circuit board module 81 may receive a user's manipulation through the touch circuit board module 85 or a user's manipulation through the wireless communication board module 86 wirelessly or wiredly. The main circuit board module 81 may transmit operational information and status information to the LED substrate module 84 and a user's mobile terminal (not shown).

In addition, on or at a center of the main circuit board 811 may be mounted a CPU provided as a controller, that is, a microcontroller, a microcomputer or a microprocessor, a plurality of switching elements or switches 812 configured to convert power received from the power circuit board module 83 into high-frequency power and supply the converted power to the working coils 312, 322, and 332, and a bridge circuit element 813. The plurality of switching elements 812 may serve as a power converting module.

A plurality of insulated gate bipolar transistors (IGBT) may be applied as the plurality of switching elements. However, a IGBT type switching element is a very heat-generating component. If such generated heat is not maintained at an appropriate level, a life span of the switch element will be shortened or a malfunction of the switch element is highly likely to occur.

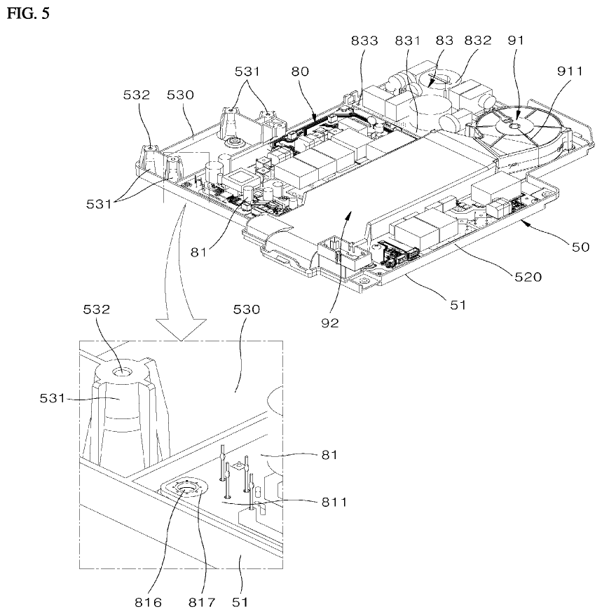

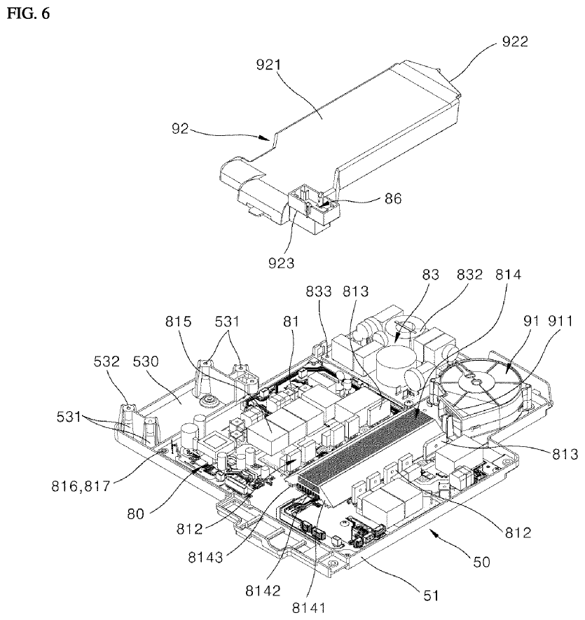

As a means for cooling the plurality of switching elements 812, a heat sink 814 configured to absorb heat generated in the plurality of switching elements 812 and the bridge circuit element 813 may be mounted on the main circuit board 811. As shown in FIG. 5, the heat sink 814 may include a hexahedral main body 8141 that extends along the frontward-rearward direction (F-R direction) of the electric range 1, and a plurality of heat dissipation fins 8143 that extends toward the main circuit board 811 from a lower surface of the body 8141.

An upper surface of the main body 8141 may be formed in a plane parallel to the main circuit board 811. Both lateral surfaces of the main body 8141 may be formed as inclined surfaces having a downward inclination.

The plurality of switching elements 812 and the bridge circuit element 813 may be attached to the lateral surfaces having the downward inclination. Accordingly, heat generated by the plurality of switching element 812 and the bridge circuit element 813 may be conducted through the lateral surfaces of the main body 8141.

A flow channel 8142 may be provided in the main body 8141, and extend in a straight line through front and rear surfaces of the main body 8141. Air may flow along the airflow channel 8142 to a ventilation fan-motor assembly 91 which will be described hereinafter. Heat from the plurality of switching elements 812 and the bridge circuit element 813 may be partially absorbed by the air flow inside of the airflow channel 8142.

Concavities and convexities (or unevennesses) may be formed on an inner surface of the airflow channel 8142 and an upper surface of the main body 8141 to expand a contact area for the air flow. The unevenness may extend in a straight line along an air flow direction, that is, in the frontward-rearward (F-R direction) to minimize flow resistance.

The plurality of heat dissipation fins 8143 may protrude from a lower surface of the main body 8141 and extend in the straight line, spaced a constant distance apart from each other. Accordingly, an air passage may be formed between each two neighboring heat dissipation fins adjacent to each other.

Some of the heat dissipation fins, in particular, the ones disposed adjacent to both lateral sides of a lower surface of the main circuit board 811 may directly contact the main circuit board 811. These heat dissipation fins may serve to support the heat sink 814 as a whole.

In a state in which the plurality of switching elements 812 and the bridge circuit element 813 are attached to the heat sink 814, the heat sink 814 may be covered by an air guide 92, which will be described hereinafter. The heat sink 814 may be spatially separated from other circuit elements outside of the air guide 92 by the air guide 92 of the ventilation module 90, and a cooling passage only for the heat sink may be formed by the air guide 92.

As shown in the drawing, a plurality of filter elements 815 may be disposed at a periphery of the air guide 92 to remove noise included in power output from the power circuit board module 83, which will be described hereinafter. The power circuit board module 83 may be disposed behind the main circuit board module 81. In general, the power circuit board module 83 may be modularized by mounting a high voltage device known as a switching mode power supply (SMPS) on the power circuit board 831. The power circuit board module 83 may convert external power into a stable-stated power before it is supplied to the switching elements 812.

The ventilation fan-motor assembly 91 of the ventilation module 90 may be disposed behind the main circuit board module 81, for example, on the base bracket 50 disposed behind the heat sink 814. The ventilation fan-motor assembly 91 may absorb external air drawn via the air inlet hole 112 of the first casing 110 and the through-hole 511 of the base bracket 50, and blow the air into the air guide 92.

As shown in the drawings, a ventilation fan applied to the ventilation fan-motor assembly 91 may not be limited; however, a sirocco fan may be used in consideration of location and spatial restrictions in which the ventilation fan is mounted. When the sirocco fan is applied, external air may be absorbed in from a bottom of the sirocco fan in a direction parallel to a rotational shaft, and the air may be accelerated and discharged radially outward.

To improve air ventilation efficiency, an outlet end 911 of the ventilation fan may be directly connected to an inlet of the air guide 92. External air forcedly blown by the ventilation fan may be drawn into the air guide 92 as a whole.

The air guide 92 may include a guide body 921 having a U-shaped cross-section and formed in a box shape, in a lower surface of which is open. The heat sink 814 may be mounted in an internal U-shaped space and the cooling passage dedicated to the heat sink 814 may direct the external air blown by the above-mentioned ventilation fan.

The guide body 921 may correspond in shape to the heat sink 814. When the guide body 921 extends along the frontward-rearward direction (F-R direction) of the electric range 1, as shown in FIG. 5, the heat sink 815 may be correspondingly arranged in a shape that extends along the frontward-rearward direction (F-R direction) of the electric range.

A rear surface of the guide body 921 may be partially open. The open rear surface may serve as an air introduction hole 922 through which the external air blown by the ventilation fan is introduced. Unlike the rear surface, a front surface and a lateral surface of the guide body 921 may be completely closed, and may perform a function of a partition wall configured to prevent the introduced external air from leaking to the outside.

The external air introduced into the cooling passage formed in the guide body 921 may flow forward while performing heat-exchange with the heat sink 814. The flow direction of the external air may be guided by the guide body 921 to finally flow in the downward direction (D-direction), thereby being discharged to the outside through the air outlet hole 111 of the first casing 110.

A substrate mounting portion or mount 923 may be integrally formed with a front surface of the guide body 921, for example, a front left or first lateral area of the front surface. The substrate mounting portion 923 may protrude from the front left area in the upward direction.

The substrate mounting portion 923 may accommodate the above-mentioned wireless communication substrate module 86. A position of the substrate mounting portion 923 may be determined as a position which may minimize the influence of high-frequency noise generated by the heater 30 and the plurality of switching elements 812. A position which is most distant from the heater 30 and the plurality of switching elements 812 may be selected.

Hereinafter, referring to FIGS. 7 to 11, a securing and supporting structure of the main circuit board module 81 and the power circuit board module 83 according to an embodiment will be described.

As described above, the main circuit board module 81 and the power circuit board module 83 may be mounted and supported on the board bracket 51 of the base bracket 50. Also, described above, the ventilation module 90 may be mounted behind the main circuit board module 81.

As described above, the base bracket 50 may include the board bracket 51 and the supporting bracket 530, and may be integrally formed with them by injection molding, for example. Compared with the conventional support structure using the plurality of supporting bolts as in the prior art, the structure for supporting the main circuit board module 81 and the power circuit board module 83 may be integrally manufactured. Accordingly, the number of the components provided in the electric range 1 according to an embodiment may be reduced remarkably.

As shown in FIG. 7, when the main circuit board module 81 and the power circuit board module 83 are separately disposed, the board bracket 51 may have an (first) area for disposing the main circuit board module 81 and another (second) area for disposing the power circuit board module 83. In addition, when they are separately disposed, the main circuit board module 81 and the power circuit board module 83 may be separately secured to the board bracket 51 of the base bracket 50 using fasteners, for example, the substrate fastening bolt B2.

For the securing using the substrate fastening bolt B2, a plurality of bolt holes 816 and 833 may be provided in the main circuit board 811 of the main circuit board module 81 and the power circuit board 831 of the power circuit board module 83 to pass the substrate fastening bolt B2 therethrough. The bolt holes 816 and 833 may be formed at positions which cause no inference with various substrate elements mounted on the main circuit board 811 and the power circuit board 831 in the assembly process. For example, the bolt holes 816 through which the substrate fastening bolts B2 pass through the main circuit board 811 may be formed in or at four corners of the main circuit board 811.

Screw bolts having a same shape and size as each other may be applied as the substrate fastening bolt B2 for securing the main circuit board 811 and coupling the power circuit board 831. Alternatively, screw bolts having a well-known standard in the art may be applied as the substrate fastening bolts B2. Through this, the manufacturing costs required for coupling the main circuit board 811 and the power circuit board 831 may be reduced.

As will be described, the main circuit board module 81 and the power circuit board module 83 may be grounded by the substrate fastening bolt B2. The substrate fastening bolt B2 may be a screw bolt having conductivity.

A ground terminal 817 for grounding through the substrate fastening bolt B2 may be formed in any one of the bolt holes 816 formed in the circuit board 811, and any one of the bolt holes 833 formed in the power circuit board 831.

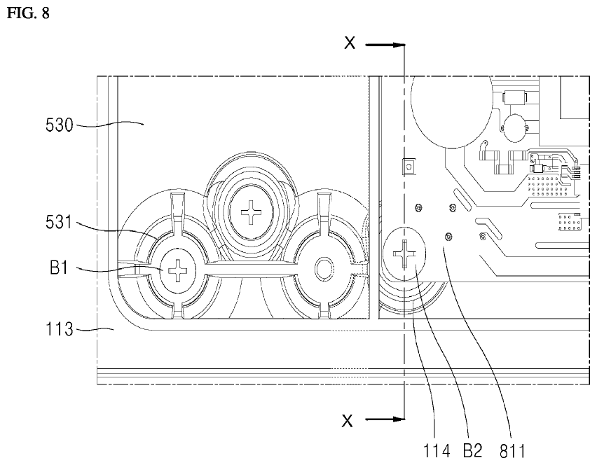

The ground terminal 817 may be formed at a position to avoid high-frequency noise generated from substrate elements mounted on the main circuit board 811 and the power circuit board 831. As shown in FIG. 8, the main circuit board 811 may be disposed adjacent to the bolt hole 816 formed in a front right corner as a top surface of the main circuit board 811. Similarly, the ground terminal 817 provided on the power circuit board 831 may be formed at a position to avoid high-frequency noise generated from the substrate elements.

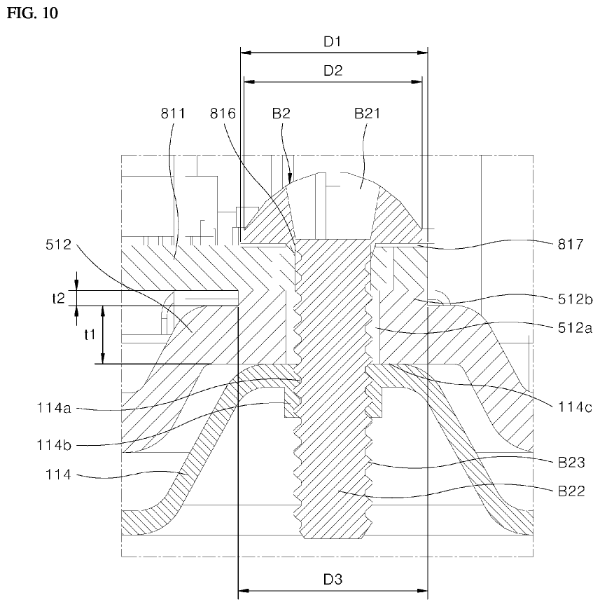

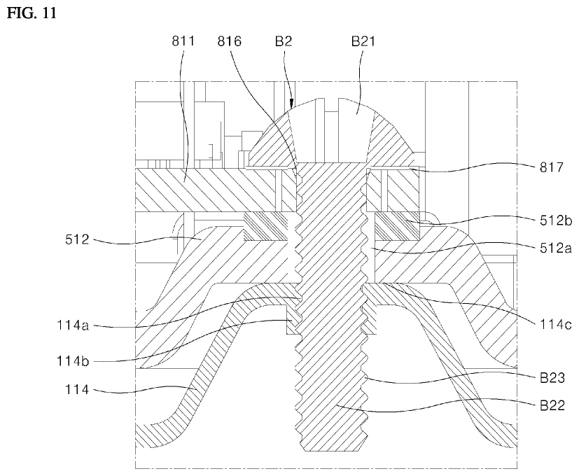

Hereinafter, an embodiment will be described as reference in which the ground terminal 817 is disposed adjacent to the bolt hole 816 formed in the front right corner as the top surface of the main circuit board 811. The ground terminal 817 may be made of a ring-shaped copper foil that surrounds the bolt hole 816, and may electrically contact the head B21 of the substrate fastening bolt B2 in the assembly process of the substrate fastening bolt B2 configured to secure the main circuit board 811, which will be described hereinafter. The configuration related to electric contact between the head B21 and the ground terminal 817 will be described hereinafter, referring to FIGS. 10 and 11. The configuration of the ground terminal 817 is already well-known in the art to which embodiments pertain, and thus, detailed description thereof has been omitted.

The substrate fastening bolts B2 having passed through the bolt holes 816 and 833 of the main circuit board 811 may penetrate the board bracket 51 of the base bracket 50 and then the first casing 110. More specifically, after penetrating the base bracket 50, the substrate fastening bolt B2 for securing the main circuit board 811 and the power circuit board 831 may be coupled to the first casing 110 functioning as the bottom surface of case 10. Accordingly, the substrate fastening bolt B2 of the electric range 1 according to an embodiment may serve as the function of securing the circuit board 811 and the function of securing the base bracket 50.

The substrate fastening bolt B2 may enter from upper surfaces of the main circuit board 811 and the power circuit board 831 and proceed in the downward direction (D-direction), to pass through the board bracket 51 of the base bracket 50 and be screw-fastened to the first casing 110. In other words, fastening of the substrate fastening bolt B2 may be configured to have a direction from the top to bottom. The downward fastening direction may be equally applied to the above-described bracket securing bolt B1, and may be equally applied to screw bolts applied as other securing means. Through this configuration, an auxiliary assembly means for turning over the product or downward coupling in the assembly process may not be necessary, so that the electric range 1 according to embodiments may have an effect of simplifying the manufacturing process and remarkably reducing the manufacturing time.

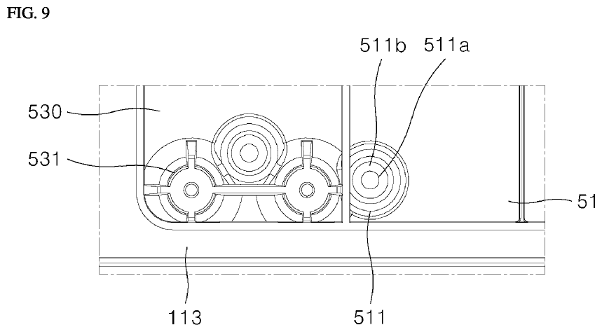

A protruding surface 512 of the base bracket 50 and the upward extending portion 114 of the first casing 110 may be disposed under the bolt hole 816 of the main circuit board 811 and the bolt hole 833 of the power circuit board 831. FIGS. 9 and 10 show an embodiment in that the protruding surface 512 of the base bracket 50 and the upward extending portion 114 of the first casing 110 are provided under the bolt hole 816 of the main circuit board 811. An embodiment has been described with reference of a supporting and securing structure of the main circuit board 811. Unless otherwise described, the same structure may be applied to the power circuit board 831.

As shown in FIGS. 9 and 10, protruding surface 512 may be provided in the board bracket 51 of the base bracket 50, and the protruding surface 512 may protrude toward the lower surface of the main circuit board 811. The protruding surface 512 may be provided in a truncated cone shape that protrudes from the lower surface of the board bracket 51, and a flat surface may be provided on a top of the protruding surface 512. An upper surface of the protruding surface 512 may directly support the lower surface of the main circuit board 811, and the flat surface may expand a contact area to stably support the main circuit board 811.

As described above, the plurality of substrate elements may be mounted on the main circuit board 811. Lead terminals (not shown) of the substrate elements may protrude downward toward the board bracket 51 from the lower surface of the main circuit board 811. The protruding surface 512 may facilitate spacing of a preset or predetermined distance between the board bracket 51 and the main circuit board 811 to prevent the lead terminals of the substrate elements from contacting the board bracket 51. Such a protruding surface 512 may be formed at a plurality of positions to support an inside of the main circuit board 811 as well as a position through which the substrate fastening bolt B2 passes, as shown in the drawings.

As shown in FIG. 10, a deformable protrusion 512b may be provided on the upper surface of the protruding surface 512 through which the substrate fastening bolt B2 passes, and the deformable protrusion 512b may protrude toward the lower surface of the main circuit board 811. For example, the deformable protrusion 512b may be formed around the bolt hole 512a and have a ring shape that surrounds the stem portion B22 of the substrate fastening bolt B2. As described above, the main circuit board 811 and the base bracket 50 may be fastened to the first casing 110 using the substrate fastening bolt B2, and may be grounded with the main circuit board 811 simultaneously.

FIG. 10 shows that a lower surface of the head B21 of the substrate fastening bolt B2 may contact the ground terminal 817 formed around the bolt hole 816 of the main circuit board 811 to be grounded with the first casing 110 formed of a electrically conductive metal plate material. As shown in the drawing, an outer diameter D1 of the ground terminal 817 formed in the ring shape may be equal to or greater than an outer diameter D2 of the head B21, thereby maintaining the grounded state between the ground terminal 817 and the head B21 effectively.

As will described hereinafter, stem portion B22 and male-screw portion of the substrate fastening bolt B2 may pass through the bolt hole 114a of the first casing 110. The fastening may proceed in such a way that the male screw portion B23 is screw-fastened to a burring portion 114b of the first casing 110. As time passes after the fastening is completed, there is a high possibility that loosening of the screw connection occurs due to external factors, such as vibration. Due to this, the electrical connection between the head B21 of the substrate fastening bolt B2 and the ground terminal 817 is highly likely to become unstable.

The deformable protrusion 512b provided on the upper surface of the protruding surface 512 provided in the board bracket 51 may be configured to generate a preload for preventing the loosening of the screw-fastening. More specifically, when the screw fastening proceeds between the male screw portion B23 of the substrate fastening bolt B2 and the burring portion 114b of the first casing 110, a height of the deformable protrusion 512b may be gradually reduced by a pressing force of the head B21 and deformation may proceed.

As shown in FIG. 10, as it is integrally formed with the protruding surface 512 of the board bracket 51, the deformable protrusion 512b may have a same material as the base bracket 50 made by plastic injection molding, for example, thereby having a predetermined elasticity due to plastic characteristics

Accordingly, the deformable protrusion 512b may be elastically deformed by the pressing force of the head B21. After the fastening of the substrate fastening bolt B2 is completed, the deformable protrusion 512b may function as a kind of a washer configured to generate a preload for preventing the loosening of the screw fastening.

A protruding height t2 of the deformable protrusion 512b from the upper surface of the protruding surface 512 may be smaller than a thickness t1 of the protruding surface 512. The protrusion height t2 may be set to have a level of almost no height, when the deformation is completed by the pressing force of the head B21 of the substrate fastening bolt B2. Once the deformation is completed, a contact area between the lower surface of the main circuit board 811 and the upper surface of the protruding surface 512 may increase and the preload of the deformable protrusion 512b may act. An outer diameter D3 of the deformable protrusion 512b may be equal to or larger than an outer diameter D2 of the head B21 of the substrate fastening bolt B2, so that the pressure applied to the head B21 may be transmitted to the deformable protrusion 512b as a whole.

As another example, FIG. 11 shows that deformable protrusion 512b is separately formed to be attached to the upper surface of the protruding surface 512. The deformable protrusion 512b may be provided separately from the board bracket 51, and may be formed of a material different from that of the board bracket 51. The deformable protrusion 512b may be formed of a material having a higher elastic modulus than the board bracket 51. When the deformable protrusion 512b is made of the material having a higher elastic modulus and deformed by the pressing force of the head B21 of the substrate fastening bolt B2, a larger restoring force may act to loosen the substrate fastening bolt B2 and a larger preload for preventing the loosening of the substrate fastening bolt B2 may be applied.

The upward extending portion 114 may be disposed under the protruding surface 512 of the board bracket 51. As described above, the upward extending portion 114 may be pressed to protrude upward (U-direction) from the downward extending portion 113. The upward extending portion may be formed in a bead shape having a substantially circular cross section and the shape may correspond to that of the lower surface of the protruding surface 512 of the board bracket 51.

An upper surface 114c of the upward extending portion 114 may include a partially flat surface. The flat surface of the upward extending portion 114 may be in surface-contact with the lower surface of the protruding surface 512 of the board bracket 51. In other words, the structure in that the upward extending portion 114 may support the board bracket 51 in a surface-contact state achieved by the flat surface.

In addition, the bolt hole 114a through which the stem portion B22 and the male screw portion B23 of the substrate fastening bolt B2 extend may be provided on the upper surface 114c of the upward extending portion 114. The burring portion 114b may protrude from a lower surface of the bolt hole 114a downward (D-direction).

The male screw portion B23 of the substrate fastening bolt B2 may be directly screw-fastened to the burring portion 114b. The burring portion 114b may be integrally formed with the upward extending portion 114. Through this, without adding auxiliary members, such as nuts, the male screw portion B23 of the substrate fastening bolt B2 may be smoothly fastened to the upward extending portion 114.

Embodiments disclosed herein provide an electric range including a single base bracket configured to support and protect a control circuit board, thereby remarkably reducing the number of components in comparison to the conventional electric range. Embodiments disclosed herein further provide an electric range including a substrate fastening bolt configured to fasten the control circuit board and the base bracket to the case simultaneously, thereby remarkably reducing manufacturing costs and manufacturing time. Embodiments disclosed herein furthermore provide an electric range in which a coupling direction of a substrate fastening bolt configured to secure a control circuit board and a base bracket to the case simultaneously is from the top to the bottom, thereby simplifying a manufacturing process.

Advantages are not limited to the above advantages, and other advantages that are not mentioned above can be clearly understood from the description and can be more clearly understood from the embodiments set forth herein. Additionally, the advantages can be realized via means and combinations thereof that are described in the appended claims.

An electric range according to embodiments disclosed herein may include a cover plate on which a heating target is disposed; a case coupled to a lower surface of the cover plat and having an accommodation space defined therein; a heating portion or heater including a working coil to which high-frequency power is applied and configured to heat the heating target by using a magnetic field generated from the working coil; a control circuit board module disposed in the accommodation space and configured to supply the high-frequency power to the working coil; a base bracket disposed between a bottom surface of the case and the control circuit board module and to which the control circuit board module is secured; and a fastener that extends through the control circuit board module and configured to secure the control circuit board module to the base bracket. The fastener may be fastened to the case through the control circuit board module and the base bracket.

The fastener may be a electrically conductive fastening bolt. The fastening bolt may include a head configured to press an upper surface of the control circuit board module; a stem portion that protrudes from the head; and a male screw portion at least partially formed in or on an outer circumferential surface of the stem portion. The stem portion may pass through the control circuit board module and the base bracket, and the male screw portion may be screw-fastened to a bottom surface of the case. The male screw portion may enter from an upper surface of the control circuit board module and proceed downward, and may pass through the base bracket to be screw-fastened to the bottom surface of the case.

The case may be formed of a electrically conductive metal plate and an upward extending portion that protrudes upward may be provided on the bottom surface of the case by a press work. The male-screw portion of the fastening bolt may be screw-fastened through an upper surface of the upward extending portion. The upper surface of the upward extending portion may be in surface-contact with a lower surface of the base bracket.

A bolt hole through which the male-screw portion of the fastening bolt passes may be formed in the upper surface of the upward extending portion. A burring portion that protrudes downward may be provided on a lower surface of the bolt hole. The male-screw portion of the fastening bolt may be screw-fastened to the burring portion.

A downward extending portion that protrudes upward may be provided on the bottom surface of the case by a press work, and the upward extending portion may protrude upward from the downward extending portion. An area of the downward extending portion may be larger than an area of the base bracket, and the base bracket may be included in a zone of the downward extending portion as a whole.

The base bracket may include a protruding surface that protrudes toward a lower surface of the control circuit board module. A lower surface of the protruding surface may be in surface-contact with the upper surface of the upward extending portion.

An upper surface of the protruding surface may be at least partially in surface-contact with the lower surface of the control circuit board module.

A deformable protrusion that protrudes toward the control circuit board module may be provided on the upper surface of the protruding surface. A shape of the deformable protrusion may be deformed by the fastening force of the fastening bolt.

The deformable protrusion may be elastically deformable. The deformable protrusion may be integrally formed with the protruding surface of the base bracket.

The deformable protrusion may be formed separately from the base bracket and attached to the protruding surface of the base bracket. The deformable protrusion may have a higher elastic modulus than the base bracket.

The deformable protrusion may be provided in a ring-shape that surrounds the stem portion of the fastening bolt. An outer diameter of the deformable protrusion may be equal to or larger than an outer diameter of the head of the fastening bolt. A protruding height of the deformable protrusion may be smaller than a thickness of the protruding surface.

When the fastening bolt is screw-fastened to the bottom surface of the case, the control circuit board module may be grounded to the case by the fastening bolt.

The control circuit board module may include a bolt hole through which the stem portion and the male screw portion of the fastening bolt pass. A ground terminal having a ring-shape may be disposed around the bolt hole of the control circuit board module, and the head of the fastening bolt may be electrically connected to the ground terminal. An outer diameter of the ring-shaped ground terminal may be equal to or larger than an outer diameter of the head of the fastening bolt.

Embodiments disclosed herein may have at least the following advantages. The electric range may include the single base bracket configured to support and protect the control circuit board, thereby remarkably reducing the number of components in comparison to the conventional electric range. Further, the electric range according to embodiments disclosed herein may include the substrate fastening bolt configured to couple the control circuit board and the base bracket to the case simultaneously, thereby remarkably reducing the manufacturing costs and manufacturing time. Furthermore, the electric range according to embodiments disclosed herein may have a coupling direction of a substrate fastening bolt configured to fasten a control circuit board and a base bracket to the case simultaneously is from the top to the bottom, thereby simplifying a manufacturing process.

Embodiments are described above with reference to a number of illustrative embodiments thereof. However, the embodiments are not intended to limit the embodiments and drawings set forth herein, and numerous other modifications and embodiments can be devised by one skilled in the art. Further, the effects and predictable effects based on the configurations in the disclosure are to be included within the range of the disclosure though not explicitly described in the description of the embodiments.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section could be termed a second element, component, region, layer or section without departing from the teachings of the present invention.

Spatially relative terms, such as “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An electric range, comprising:
a cover plate on which a heating target is disposed;
a case coupled to a lower surface of the cover plate and having an accommodation space defined therein;
a heater comprising a working coil to which high-frequency power is applied and configured to heat the heating target using a magnetic field generated from the working coil;
a control circuit board module disposed in the accommodation space and configured to supply the high-frequency power to the working coil;
a base bracket disposed between a bottom surface of the case and the control circuit board module and to which the control circuit board module is secured; and
a fastener that extends through the control circuit board module and configured to secure the control circuit board module to the base bracket, wherein the fastener is fastened to the case through the control circuit board module and the base bracket.

2. The electric range of claim 1, wherein the fastener is an electrically conductive fastening bolt.

3. The electric range of claim 2, wherein the fastening bolt comprises:
a head configured to press an upper surface of the control circuit board module;
a stem portion that protrudes from the head; and
a male screw portion at least partially formed on an outer circumferential surface of the stem portion, and wherein the stem portion passes through the control circuit board module and the base bracket and the male screw portion is screw-fastened to a bottom surface of the case.

4. The electric range of claim 3, wherein the male screw portion enters from an upper surface of the control circuit board module and proceeds downward, and passes through the base bracket to be screw-fastened to the bottom surface of the case.

5. The electric range of claim 3, wherein the case is formed of an electrically conductive metal plate, wherein an upward extending portion that protrudes upward is provided on the bottom surface of the case by a press work, and wherein the male-screw portion of the fastening bolt is screw-fastened through an upper surface of the upward extending portion.

6. The electric range of claim 5, wherein the upper surface of the upward extending portion is in surface-contact with a lower surface of the base bracket.

7. The electric range of claim 5, wherein a bolt hole through which the male-screw portion of the fastening bolt passes is formed in the upper surface of the upward extending portion, wherein a burring portion that protrudes downward is provided on a lower surface of the bolt hole, and wherein the male-screw portion of the fastening bolt is screw-fastened to the burring portion.

8. The electric range of claim 5, wherein a downward extending portion that protrudes upward is provided on the bottom surface of the case by the press work, and wherein the upward extending portion protrudes upward from the downward extending portion.

9. The electric range of claim 8, wherein an area of the downward extending portion is larger than an area of the base bracket, and wherein the base bracket is included in a zone of the downward extending portion as a whole.

10. The electric range of claim 6, wherein the base bracket comprises a protruding surface that protrudes toward a lower surface of the control circuit board module, and wherein a lower surface of the protruding surface is in surface-contact with the upper surface of the upward extending portion.

11. The electric range of claim 10, wherein an upper surface of the protruding surface is at least partially in surface-contact with a lower surface of the control circuit board module.

12. The electric range of claim 11, wherein a deformable protrusion that protrudes toward the control circuit board module is provided on the upper surface of the protruding surface, and wherein a shape of the deformable protrusion is deformed by a fastening force of the fastening bolt.

13. The electric range of claim 12, wherein the deformable protrusion is elastically deformable.

14. The electric range of claim 12, wherein the deformable protrusion is integrally formed with the protruding surface of the base bracket.

15. The electric range of claim 12, wherein the deformable protrusion is formed separately from the base bracket and attached to the protruding surface of the base bracket, and wherein the deformable protrusion has a higher elastic modulus than the base bracket.

16. The electric range of claim 12, wherein the deformable protrusion is provided in a ring-shape that surrounds the stem portion of the fastening bolt, and wherein an outer diameter of the deformable protrusion is equal to or larger than an outer diameter of the head of the fastening bolt.

17. The electric range of claim 12, wherein a protruding height of the deformable protrusion is smaller than a thickness of the protruding surface.

18. The electric range of claim 3, wherein when the fastening bolt is screw-fastened to the bottom surface of the case, the control circuit board module is grounded to the case by the fastening bolt.

19. The electric range of claim 18, wherein the control circuit board module comprises:
a bolt hole through which the stem portion and the male screw portion of the fastening bolt pass, wherein a ground terminal having a ring-shape is disposed around the bolt hole of the control circuit board module, and wherein the head of the fastening bolt is electrically connected to the ground terminal.

20. The electric range of claim 19, wherein an outer diameter of the ring-shaped ground terminal is equal to or larger than an outer diameter of the head of the fastening bolt.

21. An electric range, comprising:
a cover plate on which a heating target is disposed;
a case coupled to a lower surface of the cover plate and having an accommodation space defined therein;
a heater comprising a working coil to which high-frequency power is applied and configured to heat the heating target using a magnetic field generated from the working coil;
a control circuit board module disposed in the accommodation space and configured to supply the high-frequency power to the working coil;
a base bracket disposed between a bottom surface of the case and the control circuit board module and to which the control circuit board module is secured; and
a bolt that extends through the control circuit board module and secures the control circuit board module to the base bracket, wherein the bolt is fastened to a bottom surface of the case and presses an upper surface of the control circuit board module.

22. The electric range of claim 21, wherein the bolt is electrically conductive.
